(19) United States
(12) Patent Application Publication
(10) Pub. No.: US 2026/0155950 A1
(43) Pub. Date: Jun. 4, 2026

(54) DATA SAMPLING POINT TUNING AND TRACKING

(71) Applicant: Texas Instruments Incorporated, Dallas, TX (US)

(72) Inventors: Yaron Alpert, Hod-Hasharon (IL); Yoav Ben-Yehezkel, Netanya (IL); Michal Ben-Basat, Tel Aviv (IL)

(21) Appl. No.: 19/227,199

(22) Filed: Jun. 3, 2025

Related U.S. Application Data
(60) Provisional application No. 63/727,910, filed on Dec. 4, 2024.

(51) Int. Cl. H04L 7/033; H04L 5/16

(52) U.S. Cl. CPC H04L 7/033; H04L 5/16

(57) ABSTRACT

Methods, apparatus, systems, and articles of manufacture are described corresponding to data sampling point tuning and tracking. An example device includes a communication interface configurable to receive a data signal; and processor circuitry coupled to the communication interface and configurable to: determine a first timing for sampling the data signal for a first value of a condition; determine a second timing for sampling the data signal for a second value of the condition using the first timing and a predictive compensation model, wherein the second timing is different from the first timing; measure the condition; select the first timing or the second timing using the measured condition; and program the communication interface to sample using the selected timing.

### CROSS-REFERENCE TO RELATED APPLICATION

This patent application claims the benefit of and priority to U.S. Provisional Patent Application No. 63/727,910 filed Dec. 4, 2024, which application is hereby incorporated herein by reference in its entirety.

### TECHNICAL FIELD

This description relates generally to circuits, and, more particularly, to data sampling point tuning and tracking.

### BACKGROUND

An electrical device (e.g., a system-on-a-chip (SoC), an integrated circuit, a semiconductor device, etc.) may include components of an electronic system. These components may include on a single substrate or microchip a microcontroller, microprocessor, or one or more processor cores; static and dynamic memory; coprocessor circuits such as security circuits and graphics processing units (GPUs); serial and parallel input/output ports; and networking connectivity such as ethernet, Wi-Fi, powerline and cellular communication interfaces. A device may be coupled to external devices using synchronous half-duplex data transfer protocols, such as a quad serial peripheral interface (QSPI) or an octal serial peripheral interface (OSPI) protocol.

### SUMMARY

For data sampling point tuning and tracking, an example device includes processor circuitry coupled to the communication interface and configurable to: determine a first timing for sampling the data signal for a first value of a condition; determine a second timing for sampling the data signal for a second value of the condition using the first timing and a predictive compensation model, where the second timing is different from the first timing; measure the condition; select the first timing or the second timing using the measured condition; and program the communication interface to sample using the selected timing. Other examples are described.

For data sampling point tuning and tracking, an example method includes determining a first timing for sampling a data signal for a first value of a condition. The method also includes determining a second timing for sampling the data signal for a second value of the condition using the first timing and a predictive compensation model, where the second timing is different from the first timing. The method also includes measuring the condition. The method also includes selecting the first timing or the second timing using the measured condition. The method also includes programming a communication interface to sample using the selected timing. Other examples are described.

For data sampling point tuning and tracking, an example system includes a communication interface configurable to: transmit a clock signal and a first data signal based on tuning point parameters, and sample a second data signal based on the tuning point parameters. The system also includes a peripheral device coupled to the communication interface, the peripheral device configurable to: receive the clock signal and the first data signal; and transmit the second data signal, the second data signal corresponding to the first data signal. The system also includes processor circuitry coupled to the communication interface, the processor circuitry configurable to: determine a first timing for sampling the second data signal for a first value of an condition, the first timing corresponding to the tuning point parameters; determine a second timing for sampling the second data signal for a second value of the condition using the first timing and a predictive compensation model, where the second timing is different from the first timing; measure the condition; select the first timing or the second timing using the measured condition; and program the communication interface to use the selected timing. Other examples are described.

### BRIEF DESCRIPTION OF THE DRAWINGS

FIG. 1 is a block diagram of a device coupled to a flash memory external to the device in accordance with various examples described herein.

FIG. 2 is a block diagram of an example implementation of the communication interface of FIG. 1.

FIG. 3 illustrate example sampling windows for a data signal.

FIG. 4 is a timing diagram of a read transaction in accordance with various examples;

FIG. 5 is a timing diagram of data sampling in a read transaction in accordance with various examples (e.g. with strobes marking the sampling point as DQS and delayed DQS).

FIG. 6 illustrates data paths of the device of FIG. 1 that results in delay.

FIG. 7 illustrates a multiplexer for selecting an amount of delay corresponding to FIG. 6.

FIG. 8 is a block diagram of an example implementation of the core processor 102 of FIG. 1.

FIGS. 9-10 are flowcharts representative of a method, instructions, and/or operations that may be executed to implement the core processor of FIG. 5.

FIGS. 11A and 11B illustrate example polygon calculation and representations of successful sampling points.

FIG. 12 illustrates an example of shifted sampling.

FIG. 13 illustrates an example of shifted samples that results in different polygon representations.

FIG. 14 illustrates different polygon representations based on shifted sampling.

FIG. 15 illustrates polygon representation and sampling point adjustments based on a predictive compensation model.

FIG. 16 illustrates alternative polygon representation and sampling point adjustments based on a predictive compensation model.

FIG. 17 illustrates stability indicators for different polygon representations.

FIG. 18 is a block diagram of an example processing platform including programmable circuitry structured to execute, instantiate, and/or perform the example machine readable instructions and/or perform the example operations of FIGS. 9-10 to implement the controller of FIG. 8.

The same reference numbers or other reference designators are used in the drawings to designate the same or similar (functionally and/or structurally) features. The drawings are not necessarily to scale. Generally, the same reference numbers in the drawing(s) and this description refer to the same or like parts. Although the drawings show regions with clean lines and boundaries, some or all of these lines and/or boundaries may be idealized. In reality, the boundaries and/or lines may be unobservable, blended and/or irregular.

### DETAILED DESCRIPTION

A device (e.g., an SoC, an integrated circuit, a semiconductor device, etc.) may include a communication interface, such as a serial peripheral interface (SPI), that electrically couples the device to a peripheral device, such as a flash memory device. The communication interface may be an Octal SPI (OSPI), a Quad SPI (QSPI), inter-integrated circuit (I2C), or other communication interface suitable for coupling the device to the peripheral device. Timing parameters of the SPI that control program and read transactions with the peripheral device are referred to as tuning point parameters (also referred to as sampling point parameters, tuning points, or sampling points). Tuning point parameters include transmit clock programmable delay line (PDL) delay (TX delay), receive clock PDL delay (RX delay), and RD cycle. The RD cycle is a number of cycles to delay (e.g., dummy cycles) an SPI reference clock for reading data received by the SPI from the flash device.

At different die conditions (e.g., different tuning parameters, operating temperatures, age, etc.) of the device, some ranges of tuning points result in successful transactions between the SPI and the flash device, while others do not. A successful tuning point allows the SPI to reliably program and read data to/from the flash device. An unsuccessful tuning point causes the SPI to fail altogether or to unreliably program and read data to/from the flash device. At different die conditions, the ranges of tuning points that are successful and unsuccessful also change. Traditionally, after a device is first coupled to a flash device, a tuning point for the SPI is programmed and is not reprogrammed during subsequent operation of the device. As a result, as the device die operating temperature, age, humidity, environmental impedance or conductance, clock jitter, crosstalk of the input line, grounding (e.g., board and device grounding), parallel activity, input voltage, corner position of chip on wafer, etc. change during operation, the originally programmed successful tuning point of the SPI may become a sub-optimal (e.g., unsuccessful) tuning point. Accordingly, traditional techniques require long service interrupting recalibration to determine a new tuning point, which results in downtime, and consumption of energy and resources.

Examples described herein select communication interface tuning point parameters for transactions with a peripheral device, such as a flash device, during configuration that will successfully program and read to/from the peripheral device over a wider range of die conditions than other successful tuning point parameters. Additionally, examples described herein can determine different tuning point parameters that correspond to different conductions, such as environmental conditions or die conditions. Environmental conditions may correspond to temperature, humidity, environmental impedance or conductance, etc. A die condition may correspond to age of the die, age of one or more components on the die, number or time of the die or components on the die in use, clock jitter, crosstalk on the input line, grounding, parallel activity, input voltage, structure of the die, location of the die on the wafer, and/or any other physical condition or characteristics of the die and/or components on the die. In this manner, examples described herein can dynamically adjust tuning point parameters based on monitored conditions (e.g., environmental condition(s) and/or die condition(s)) without needing to recalibrate the tuning point parameters. Examples described herein search subsets of candidate tuning point parameters by adjusting tuning point parameters (e.g., RX delay, TX delay, a reference clock, and/or a protocol configuration) and/or shifted sampling delays (e.g., RD cycles) and determining whether the adjusted tuning point parameters and/or shifted sampling delays resulted in a successful read data from the peripheral device via the communication interface.

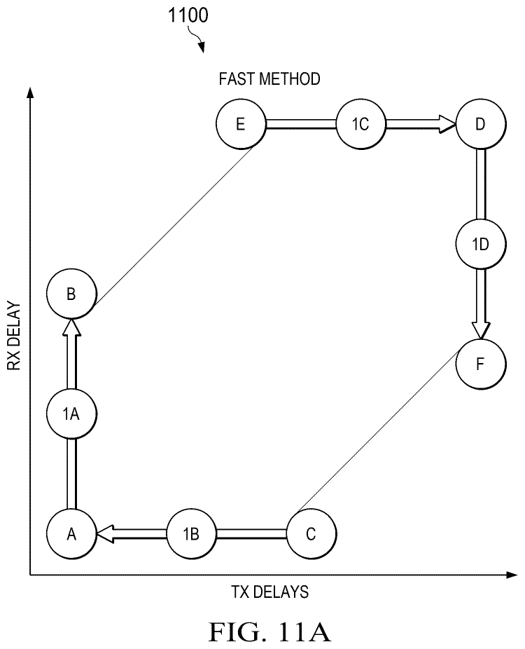

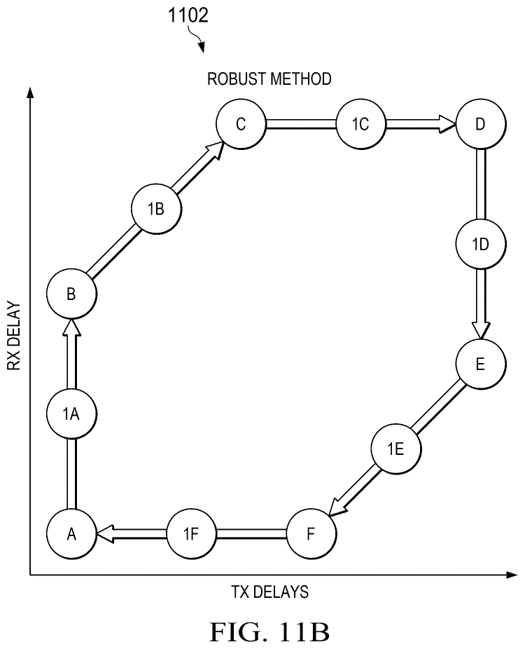

A set of successful tuning points (e.g., an RX delay, a TX delay, a reference clock, a protocol configuration used to sample) may be represented as one or more polygons (e.g., a polygon for each shifted delay) on a graph of RX delay and TX delay (see, e.g., FIGS. 11A, 11B, and 14-17). Although all the points in the one or more polygons per specific reference clock and protocol configuration correspond to RX and TX delays that resulted in successfully read data from the peripheral device via the communication interface, tuning points closer to the edge of a polygon are less stable. For example, as described above, conditions, such as environmental conditions and/or die conditions, can adjust where the edges of the polygon occur. Accordingly, examples described herein select a sampling/tuning point from the polygon of successful tuning points based on the position of the sampling/tuning point within the polygon (e.g., a weighted center and/or a point whose distance to any edge of the polygon is highest). After the initial polygon(s) and corresponding sampling/tuning point(s) are determined, examples described herein can generate additional sampling/tuning points that correspond to different conditions (e.g., environmental and/or die) using a predictive compensation model. Examples described herein determine the sampling/tuning points for the additional polygons and corresponding stability indication values which can be used to determine a final sampling/tuning point and/or used for particular conditions during operation of the device. Examples described herein select one of the sampling/tuning points from the multiple generated sampling/tuning points based on the stability indication values (e.g., the selected sampling/tuning point corresponds to the sampling/tuning point with the largest stability indicator value). Because the generation of the final sampling/tuning point is based on multiple factors and/or conditions, the final sampling/tuning point can be more robust and longer lasting than traditionally selected sampling/tuning points. The above is defined for a specific operation profile. Different optimal sampling points may apply to different operation profiles, if multiple are supported (e.g. SDR (Single Data Rate) vs. DDR (Double Data Rate), frequency of the flash, access to flash registers vs. memory, etc.).

The techniques of this disclosure may provide for the quick adjustment of a sampling point in response to changing conditions. For example, a device can store one or more pre-generated sampling points for use when a condition has changed. The selected sampling point may be more accurate, thereby increasing the likelihood of sampling the correct bits on a receive line.

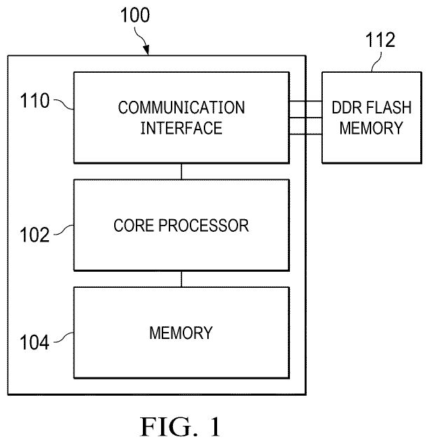

FIG. 1 is a block diagram of an example device 100 coupled to an example flash memory 112 in accordance with various examples. Although FIG. 1 corresponds to a connection to the example flash memory 112, the flash memory 112 can be replaced with a different type of peripheral device (e.g., a different type of memory, another microcontroller, or a display controller) in some implementations. The device 100 includes an example core processor 102 coupled to example memory 104. The memory 104 is configured to store instructions that, when executed by the core processor 102, cause the core processor 102 to perform the various functionalities described herein.

The core processor 102 of FIG. 1 is further coupled via an example communication interface 110 to the flash memory 112. Additionally, the core processor 102 may be coupled to one or more communication links via a second communication interface to facilitate communication with other devices. The device 100 may also include other circuits and processors that are not shown in FIG. 1. As further described below, the core processor 102 performs a sampling/tuning point selection protocol by transmitting instructions to the communication interface 110 to adjust parameters of the communication interface 110, sending known data to the flash memory 112, sampling the stored data from the flash memory 112, and comparing the results to the known data to determine if the sampling was successful or not. The core processor 102 generates one or more polygon representations of parameters that resulted in successful sampling and selects a sampling/tuning point based on the one or more polygon representations, as further described below. Additional example details of the selection of sampling points can be found in commonly assigned U.S. Pat. No. 11,935,613, entitled “Method for Tuning an External Memory Interface,” filed Jul. 30, 2021, which is incorporated by reference in its entirety.

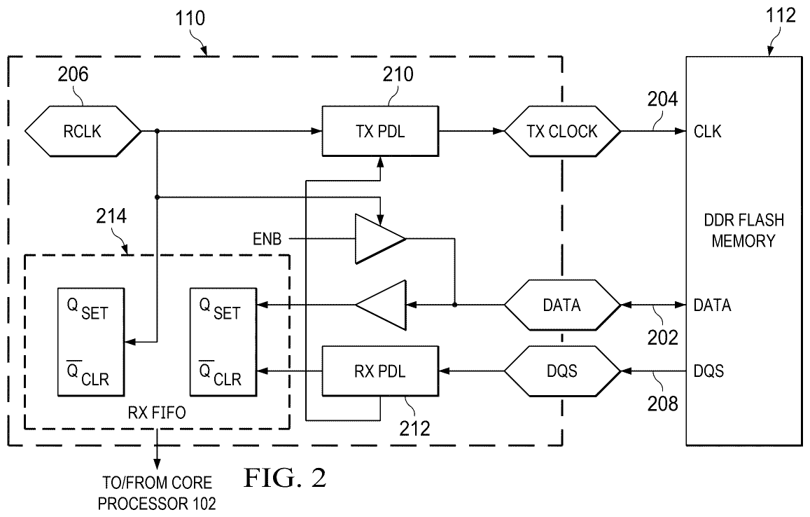

FIG. 2 is a block diagram of the communication interface 110 with the flash memory 112. The communication interface 110 is coupled to the flash memory 112 by example data lines 202, an example SPI clock line 204, and an example data strobe (DQS) line 208. The data lines 202 are bidirectional, allowing each of the communication interface 110 and the flash memory 112 to send data to each other in different phases of a transaction. For example, the core processor 102 controls the communication interface 110 to provide an OSPI clock to the flash memory 112. The OSPI clock is generated by delaying the reference clock through the TX PDL 210. The flash memory 112 uses the clock to capture the command and address during the command and address phases. In some examples, the communication interface 110 is a half-duplex system-based interface such as an SPI, an OSPI, a QSPI, or XSPI etc. The flash memory 112 uses the SPI clock line 204 to capture command and address information from the data lines 202 during command and address phases of a transaction. The flash memory 112 also uses the SPI clock line 204 to capture data from the data lines 202 during a data phase of a program transaction. The communication interface 110 uses a delayed copy of the DQS line 208 to capture data from the data lines 202 during the data phase of a read transaction.

The communication interface 110 includes an internal reference clock 206 (e.g., a clock signal) that is delayed by a TX PDL 210 to form the SPI clock line 204. The value of the TX PDL 210 delay is referred to as ‘TX delay.’ The core processor 102 can adjust the TX delay as part of the sampling/tuning point selection protocol. Edges of signal pulses on the DQS line 208 are aligned with data transitions on the data lines 202 from the flash memory 112 during the data phase of a read transaction. The DQS line 208 is delayed by a RX PDL 212 to cause a received first-in-first out (FIFO) shift register to sample data on the data lines 202 after the values have settled. The value of the RX PDL 212 delay is referred to as ‘RX delay.’ The core processor 102 can adjust the RX delay as part of the sampling/tuning point selection protocol.

A ‘round trip delay’ of data may be defined as the time from a reference clock 206 edge to a sampling time in the communication interface 110 of data from the flash memory 112 that is triggered by that edge. The delay of the TX PDL 210, a travel time of the clock over the SPI clock line 204, an output delay of the flash memory 112, and the delay of the RX PDL 212, create the round trip delay. As described above, the communication interface 110 samples the data lines 202 into the RX FIFO 214 using the DQS line 208 as delayed by the RX PDL 212. The data is read by the communication interface 110 out of the RX FIFO 214 using the reference clock 206. The data that is read is passed to the core processor 102 to determine whether the reading, also referred to as sampling, was successful.

The communication interface 110 expects the first byte of data to be captured within a specific cycle of the reference clock 206 (the target cycle or RD cycle), and all remaining data to be captured in succeeding cycles of the reference clock 206. In some cases, the round trip delay is longer than the period of the reference clock 206 and the target cycle is moved to a following cycle of the reference clock 206 to read data successfully on the data lines 202.

As further described below, the core processor 102 selects a preferred tuning point (values for the TX delay, RX delay, and RD cycle) for the communication interface 110 to use with the flash memory 112 based on the sampling/tuning point detection protocol described herein. The sampling/tuning point detection protocol includes generating one or more polygon representation of successful sampling of data based on different tuning point parameters and/or conditional parameters and selecting a sampling/tuning point from the one or more polygon representation based on the stability of the points within the one or more polygon representations.

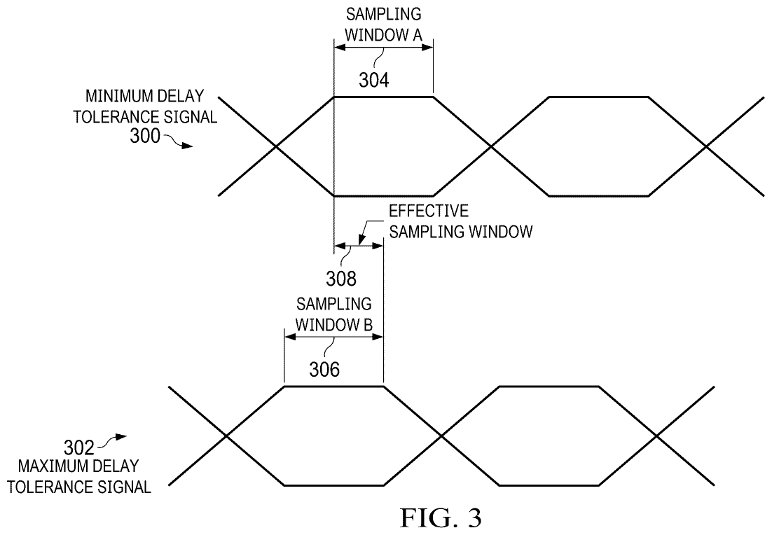

FIG. 3 is a timing diagram illustrating an example first data signal 300 corresponding to minimum delay tolerance and a second data signal 302 corresponding to maximum delay tolerance. The first data signal corresponds to a first sampling window 304 and the second data signal 302 corresponds to a second sampling window 306. The communication interface 110 will successfully sample the first data signal 300 so long as the data is sampled within the sampling window 304. Additionally, the communication interface 110 will successfully sample the second data signal 302 so long as the data is sampled within the sampling window 306. However, the data may be shifted anywhere between the first data signal 300 and the second data signal 302. Thus, the effective sampling window 308 corresponds to the sampling window that will result in successful sampling of the data signal whether it corresponds to the first data signal 300, the second data signal 302, or any other data signal shifted therebetween. Sampling/tuning point parameters may be selected such that the sampling occurs within the effective sampling window 308, or one or more estimations of the effective sampling window 308. However, such a technique for generating sampling/tuning point parameters based on the effective sampling window 308 are less robust to endure long-term effects causing significant degradation in performance due to sensitivity to clock-to-data skew, narrow sampling window, limited real-time compensation/complexity in calibration logic, calibration time overhead, hitter on signals, etc.

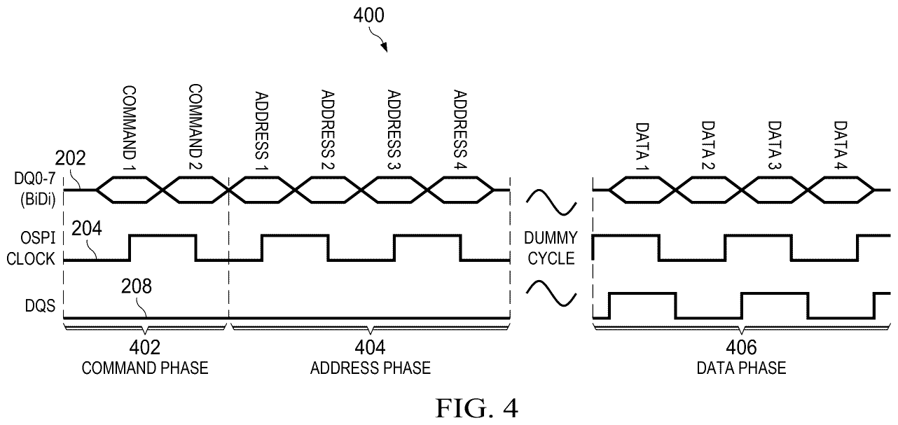

FIG. 4 shows an example timing diagram 400 of a read transaction performed by the communication interface 110 of FIGS. 1 and 2 in accordance with examples described herein. The read transaction includes an example command phase 402, an example address phase 404, and an example data phase 406. In the command phase 402, the communication interface 110 can send command bytes on the data lines 202 and the reference clock 206 as delayed by TX PDL 210 on the SPI clock line 204. The command bytes may correspond to a command to read data from a particular address where the data stored in the particular address is known. In the address phase 404, the communication interface 110 sends address bytes on the data lines 202 and the reference clock 206 as delayed by TX PDL 210 on the SPI clock line 204. The address bytes can reference the address of the data to be read. One or more dummy cycles are inserted after the address phase 404 to provide the flash memory 112 time to access the addressed memory. In the command phase 402 and the address phase 404, the flash memory 112 can sample (e.g., read) the command bytes and the address bytes, respectively from the data lines 202. In the data phase 406, the flash memory 112 can send data bytes on the data lines 202 and the DQS signal on the DQS line 208. As further described above, the core processor 102 can compare the sampled data to the known data to determine if the sample was a success or a failure. The core processor 102 can transmit the same command multiple times for different tuning parameters to generate the polygon representation of the successful samples, as further described above.

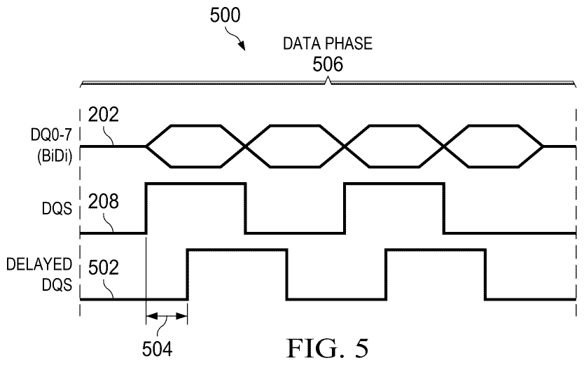

FIG. 5 shows an example timing diagram 500 of data sampling in the communication interface 110 during a read transaction in accordance with various examples. The read data bytes on the data lines 202 and the DQS signal on the DQS line 208 are as shown in FIG. 4. An example delayed DQS signal 502 is the DQS line 208 as delayed by the value of the RX PDL 212 delay, as shown in an example RX delay 504.

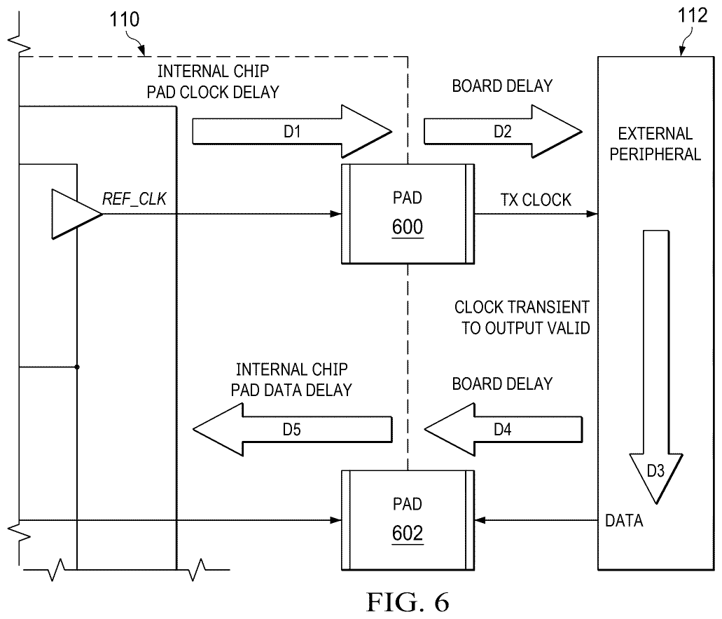

FIG. 6 illustrates RX reference clock sampling options, illustrating the ability of the core processors 102 to select between 3 options: A) RX-ref A: no loopback; B) RX-ref B: Pad loopback; and C) RX-ref C: external loopback or DQS. For each of these options a different RD cycle can be selected. Accordingly, each of the three options (times the amount of RD cycle per option) will result in a different polygon representation when implementing the sampling/tuning point selection protocol. For tuning and tracking the data sampling/tuning point, ensuring that the sampling edge of the clock aligns correctly with the data bits, the core processor 102 can also select a method for generating a reference RX ref clock used for tuning and tracking the data sampling/tuning point based on internal (relative to the data sent) or external (relative to the arriving samples). FIG. 6 includes the communication interface 110 and the flash memory 112 of FIG. 1. FIG. 6 further includes example pads 600, 602 (e.g., terminals, interfaces, etc.) that allow a wire, etch, etc. to connect the communication interface 110 to the flash memory 112.

FIG. 6 illustrates TX and RX clock non-linear delay fluctuation. D1 and D5 represent the internal chip pad clock delay. The delay between the TX clock inside the chip and the one that returns on the chip pads due to internal chip delays, may vary from chip to chip.

D3 represents a clock transient to output valid. Clock transient to output valid is a characteristic of a peripheral device. The delay between the SPI clock transition on the external peripheral clock pin and the time when valid data is driven by the peripheral device. D3 may be a nondeterministic delay (tmin to tmax) that can include the internal register and data sectors of the peripheral device.

D2 and D4 represent board delays, e.g., where both devices are coupled to a circuit board. The impedance of the lines, which should correspond to the impedance of the external peripheral input/outputs. The board delays D2 and D4 are caused by the length of the wires/lines. The board delays D2 and D4 can exist even if the lines are perfectly impedance matched to the external peripheral's input/outputs.

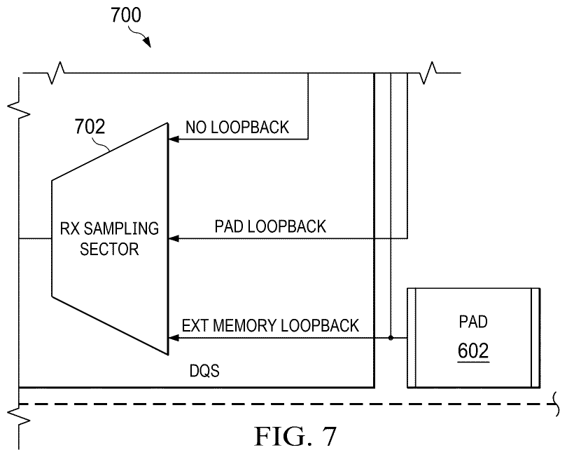

FIG. 7 is an example circuit 700 that can select an RD cycle for sampling based on the three options described above in conjunction with FIG. 6. The circuit 700 of FIG. 7 includes an example multiplexer (MUX) 702. The MUX 702 includes three inputs and an output. A first input of the MUX 702 is corresponding to RX-ref A: no loopback representing internal chip pad clock delays D1+D5 in FIG. 6. The second input of the MUX 702 is corresponding to B) RX-ref B: Pad loopback representing both internal chip pad clock delays as well as board delays D1+D2+D4+D5 in FIG. 6. The third input of the MUX 702 is corresponding to RX-ref C: external loopback or DQS representing all the delays internal chip pad clock delays, board delays and clock transient to output valid delay, i.e. D1+D2+D3+D4+D5. The output of the MUX 702 is coupled to a data point sampler that enforces the sampling of the data at the selected delay by the MUX 702. The core processor 102 can apply a control signal to a select input of the MUX 702 to control which amount of delay to perform during sampling. Each amount of delay (as referred to as shifted sampling) results in a different polygon representation when determining a sampling/tuning point.

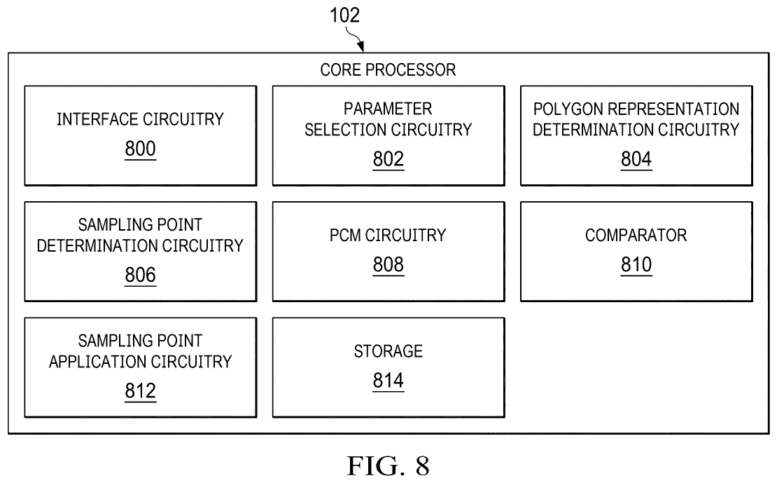

FIG. 8 is a block diagram of an example implementation of the core processor 102 of FIG. 1. The core processor 102 of FIG. 8 includes interface circuitry 800, example parameter selection circuitry 802, example polygon representation determination circuitry 804, example sampling/tuning point determinization circuitry 806, example predictive compensation model (PCM) circuitry 808, an example comparator 810, example sampling/tuning point application circuitry 812, and example storage 814.

The interface circuitry 800 of FIG. 8 activates the transaction over the interface lines themselves (e.g. clock, data). Additionally, the interface circuitry transmits instructions to the TX PDL 210 and/or the RX PDL 212 to adjust the tuning point parameters (e.g., the TX delay, RX delay, and/or RD delay) as part of a sampling/tuning point selection protocol. Additionally, the interface circuitry 800 can send instructions (e.g., via the ENB terminal of the communication interface 110 to read data at a particular address. The data at the address is known data and/or known data that has been previously written to. Additionally, the interface circuitry 800 can receive samples from the RX FIFO 214 received from the flash memory 112 after data sampling.

The parameter selection circuitry 802 of FIG. 8 selects the tuning parameters for applying for the sampling/tuning point selection protocol. For example, the parameter selection circuitry 802 can determine the sampling RX reference clock sampling option (e.g., RD cycle and the options described in conjunction with the above FIG. 6) for generating a polygon based on successful sampling/tuning points for different tuning point parameters. Additionally, the parameter selection circuitry 802 determines the amount of TX delay and RX delay to apply for each sample of the sampling/tuning point selection protocol when generating the polygon representation for the selected RD cycle value.

The polygon representation determination circuitry 804 of FIG. 8 generates a polygon representation of successful sampling/tuning points for each tunable degree of freedom (e.g. RD cycle which can be for each selected RX reference clock sampling options). The polygon includes points represented by the TX delay and the RX delay that resulted in a successful sampling of data. To generate a polygon representation, the polygon representation determination circuitry 804 selects a first TX delay and a first RX delay and instructs the communication interface 110 to access known data from the flash memory 112 based on the first TX delay, the first RX delay, and the RD delay. After the communication interface 110 sends the instruction to the flash memory 112 and samples the data that the flash memory 112 returned, the interface circuitry 800 accesses the sampled data. The polygon representation determination circuitry 804 determines whether the sampled data matches the expected known data. If the polygon representation determination circuitry 804 determines that the sampled data matches the expected known data, the polygon representation determination circuitry 804 tags the tuning parameters as a success. If the polygon representation determination circuitry 804 determines that the sampled data does not match the expected known data, the polygon representation determination circuitry 804 tags the tuning parameters as a failure. The polygon representation determination circuitry 804 repeats this process for various different TX delays and RX delays until a polygon representation is determined for the RD cycle value. After the polygon representation is determined, the polygon representation determination circuitry 804 can repeat the process for one or more different RD delay values and RX reference clocks to generate one or more additional polygon representations.

The sampling/tuning point determination circuitry 806 of FIG. 8 selects a sampling/tuning point from the one or more polygon representations generated by the polygon representation determination circuitry 804. As described above, although all the sampling/tuning points identify the combinations of TX delay and RX delay that resulted in a successful sampling for a particular RD delay and the RX reference clocks, the stability of the sampling/tuning points are all different. Accordingly, the sampling/tuning point determination circuitry 806 selects a sampling/tuning point (e.g., one of the tuning points that make up a polygon representation) that represents a desirable polygon according to selected optimization and stability criteria, e.g. the largest distance from the polygon representation boundaries (e.g., the tuning point that has the highest distance from the include of the polygon to its closest boundary). The points further away from an edge are more stable across different conditions (e.g., environmental or die) than points closer to the edge. In some examples, the sampling/tuning point determination circuitry 806 determines a sampling/tuning point for a given polygon using the below polygon centroid formula (also referred to as a center of mass or center of gravity), in the below Equations 1 and 2

$${C}_{x} = \frac{1}{6 A} {\sum }_{i = 0}^{n - 1} ( {x}_{i} + {x}_{i + 1} ) ( {x}_{i} {y}_{i + 1} - {x}_{i + 1} {y}_{i} ) \qquad ( Equation 1 )$$

$${C}_{y} = \frac{1}{6 A} {\sum }_{i = 0}^{n - 1} ( {y}_{i} + {y}_{i + 1} ) ( {x}_{i} {y}_{i + 1} - {x}_{i + 1} {y}_{i} ) \qquad ( Equation 2 )$$

In the above-Equations 1 and 2, Cx is the TX delay for the selected sampling/tuning point, Cy is the RX delay for the selected sampling/tuning point, x represents a x coordinate of the polygon representation and y represents a y coordinate of the polygon representation, and A is the area of the polygon. The sampling/tuning point determination circuitry 806 determines the area of the polygon using the below Equation 6.

$$A = \frac{1}{2} {\sum }_{i = 0}^{n - 1} ( {x}_{i} {y}_{i + 1} - {x}_{i + 1} {y}_{i} ) \qquad ( Equation 3 )$$

In some examples, the sampling/tuning point determination circuitry 806 computes the selected sampling/tuning point (e.g., the centroid) of the polygon as the weighted sum of the centroids of a partition of the polygon into triangles. After the sampling/tuning point determination circuitry 806 selects a sampling/tuning point for each of the polygon representation(s), the sampling/tuning point determination circuitry 806 determines the sampling/tuning point stability point based on the distance of the selected sampling/tuning point to the nearest edge of the polygon representation (e.g., using a distance formula).

The predictive compensation model circuitry 808 of FIG. 8 generates additional sampling/tuning points from the selected sampling/tuning point(s) that correspond to different conditions (e.g., temperature, humidity, age, structure, location of die on wafer, etc.) by adjusting the selected sampling/tuning point(s) and corresponding stability indicator(s) using a predictive compensation model (PCM). The PCM may be a mathematical function that has been developed based on estimations of the effective one or more conditions to a polygon representation. For example, the predictive compensation model circuitry 808 can generate a PCM that extrapolates a polygon's dependency for input condition parameters (e.g., temperature, age, etc.). The predictive compensation model circuitry 808 can generate a PCM by collecting information about polygon geometry and material properties (e.g., shape, size, boundary conditions, etc.) and characterizing how the conditions change the structure of a polygon. For example, one or more conditions may adjust the structure of the polygon in a uniform or disproportionate manner. After the effect of one or more conditions to the polygons have been determined, the predictive compensation model circuitry 808 can model the effect using various modeling approaches (e.g., finite element method, computational fluid dynamics, etc.). The predictive compensation model circuitry 808 can use simulation software or a programming environment to apply the model approaches. The predictive compensation model circuitry 808 defines a mathematical model (e.g., function or formula) that describes the relationship between one or more conditions and the effect on a stability point and/or corresponding stability point stability indicator. The mathematical formula may be an empirical model or a mechanistic model. An empirical model is a mathematical representation that is derived directly from observations or experiments, without explicit consideration for underlying physical principles. In other words, an empirical model is created by analyzing data and identifying relationships between variables through statistical methods, regression analysis, or machine learning techniques. A mechanistic model is a mathematical representation that describes the underlying physical principles and mechanisms governing a system's behavior. These models aim to capture the intrinsic dynamics, processes, and relationships of the system being studied. The predictive compensation model circuitry 808 applies the PCM to generate different sampling/tuning points and corresponding sampling/tuning point stability indicators that correspond to different conditions or trends of the conditions changes. The PCM computation can be either locally by the core processor 102 or remotely (e.g. computed by another computation element and sent over an interface 110 or other to the core processor 102). For example, the predictive compensation model circuitry 808 can generate a first sampling/tuning point and corresponding stability indicator for a first temperature range and/or age range, a second sampling/tuning point and corresponding stability indicator for a second temperature range and/or age range, etc.

The comparator 810 of FIG. 8 compares the stability indicators of the generated sampling/tuning points to determine which stability indicator is largest. The larger the stability indicator, the more stable the sampling/tuning point parameters (tuning point parameters) for the corresponding sampling/tuning points are. Accordingly, the comparator 810 determines the most stable sampling/tuning point parameters based on the generated sampling/tuning point parameters with the largest stability indicator taking into account changing environment conditions trends. The comparator 810 outputs the final selected sampling/tuning point based on the comparison.

The sampling/tuning point application circuitry 812 of FIG. 8 programs the communication interface 110 to operate based on the tuning parameters of the final selected sampling/tuning point. For example, the sampling/tuning point application circuitry 812 may program the communication interface 110 to operate based on the RD cycle, an amount of TX delay, and/or the amount of RX delay that corresponds to the final selected sampling/tuning point at a certain RX reference clock. Additionally, the sampling/tuning point application circuitry 812 monitors the conditions during operation with the selected sampling/tuning point. For example, the sampling/tuning point application circuitry 812 may monitor temperature, age of the device 100, etc. As described above, the PCM circuitry 808 may generate different sampling/tuning points for different condition(s). In this manner, if the sampling/tuning point application circuitry 812 determines that the measured condition(s) no longer correspond to the selected sampling/tuning point, the sampling/tuning point application circuitry 812 can select another sampling/tuning point generated by the predictive compensation model circuitry 808 that corresponds to the measured condition(s). Accordingly, the sampling/tuning point application circuitry 812 provides on-the-fly tuning and tracking for different conditions without the need to recalibrate the sampling/tuning point.

The example storage 814 of FIG. 8 stores generated sampling/tuning points generated by the sampling/tuning point determination circuitry 806 and/or the PCM circuitry 808 that correspond to stable sampling/tuning point parameters for different conditions (e.g., temperature ranges, age ranges, etc.). As described above, the sampling/tuning points are initially generated during calibration and stored in the storage 814. In this manner, during application of a sampling/tuning point, the sampling/tuning point application circuitry 812 can access the sampling/tuning points for on-the-fly tuning based on changes in conditions.

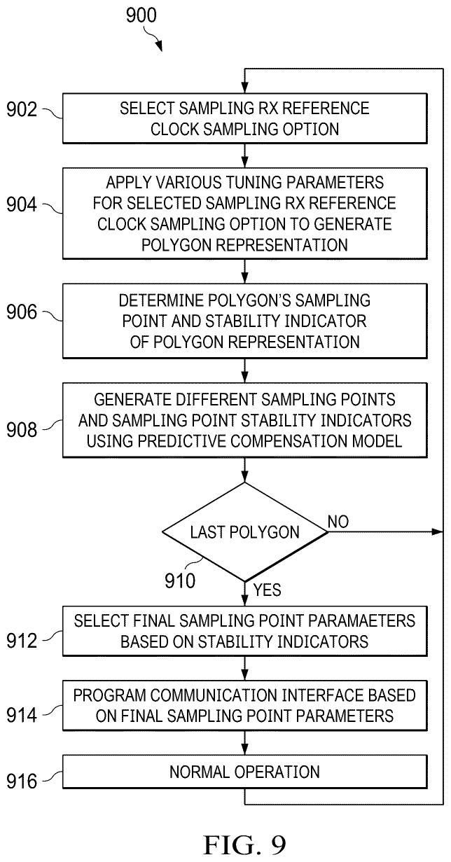

FIG. 9 is a flowchart representative of a method and/or example operations 900 that may be executed and/or instantiated by core processor 102 of FIGS. 1 and 8. The operations 900 can be performed by any one or combination of the circuitry shown in FIGS. 1-5. Although the instructions and/or operations of FIG. 9 are described in conjunction with the core processor 102 of FIGS. 1 and 8, the instructions and/or operations may be described in conjunction with any type of circuit that implements processing circuitry. Some processes shown in FIG. 9 may be performed in orders other than described, and many processes may be performed concurrently in parallel. Furthermore, processes shown in FIG. 9 may be omitted or substituted in some examples of the present description.

The machine-readable instructions and/or the operations 900 of FIG. 9 begin at block 902, at which the parameter selection circuitry 802 selects a sampling RX reference clock sampling option (e.g., A) RX-ref A: no loopback; B) RX-ref B: Pad loopback; or C) RX-ref C). After selected, the interface circuitry 800 can apply a control signal to the select terminal of the MUX 702 of FIG. 7 to apply the selected sampling RX reference clock sampling option corresponding to an RD cycle.

At block 904, the polygon representation determination circuitry 804 applies various different tuning/sampling parameters for the selected sampling RX reference clock sampling option to generate a polygon representation of the successful sampling/tuning point parameters (e.g., a two dimensional (2D) successful sampling plan polygon). For example, the parameter selection circuitry 802 selects a first set of tuning parameters (e.g., RX delay and TX delay), samples data from a location of the flash memory 112 based on the first set of tuning parameters and determines whether the sampled data matches the known data for the location. If the sampled data matches the known data, the polygon representation determination circuitry 804 marks the point corresponding to the first set as a success, to be included in a polygon representation. If the sampled data mismatches the known data, the polygon representation determination circuitry 804 marks the point corresponding to the first set as a failure, not to be included in the polygon representation. This process is repeated for multiple sets of tuning parameters until a polygon representation of the successful points is generated.

At block 906, the sampling/tuning point determination circuitry 806 determines a sampling/tuning point and corresponding stability indicator for the polygon representation. For example, the sampling/tuning point determination circuitry 806 can determine the sampling/tuning point using the above Equations 1-3 and determine the corresponding stability indicator based on a distance between the sampling/tuning point and the nearest point on an edge of the polygon representation. At block 908, the PCM circuitry 808 generates different sampling/tuning points and corresponding stability indicators using a predictive compensation model. As described above in conjunction with FIG. 8, the PCM models the effect of one or more conditions on the stability point and corresponding stability indicators. Accordingly, the PCM circuitry 808 applies the PCM to the selected stability point and corresponding stability indicator to generate different stability points and corresponding stability indicators for different condition(s).

At block 910, the parameter selection circuitry 802 determines if another polygon can be generated based on whether all of the RD cycles and RX reference clock sampling options have been utilized to generate a polygon. If there is another RD cycle/RX reference clock sampling option that has not been used to generate a polygon, the process is repeated for the remaining RD cycle(s)/RX reference sampling option(s). Thus, if the parameter selection circuitry 802 determines that the generated polygon representation is not the last polygon representation to generate (block 910: NO), control returns to block 902 to repeat the process for a subsequent RD cycle/RX reference clock sampling option.

If the parameter selection circuitry 802 determines that the generated polygon representation is the last polygon representation to generate (block 910: YES), the comparator 810 selects final stability point parameters (e.g., a TX delay, an RX delay, and a RD cycle) based on the stability indicators for the generated/selected sampling/tuning points for the generated polygons and/or based on the different conditions (block 912). For example, the process of steps 902-610 may result in three polygon representations, each with a corresponding sampling/tuning point, and multiple PCM-adjusted sampling/tuning points. Each sampling/tuning point corresponds to a stability indicator. The comparator 810 determines the largest stability indicator and selects the final sampling/tuning point parameters that correspond to the largest stability indicator (e.g., the RX delay, TX delay, and RD cycle that resulted in the largest stability indicator). In some examples, the largest stability indicator can be substituted with a different optimization criterion for stability.

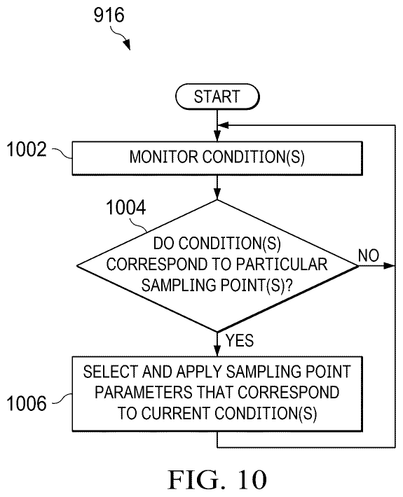

At block 914, the sampling/tuning point application circuitry 812 programs the communication interface 110 based on the final sampling/tuning point parameters. For example, the sampling/tuning point application circuitry 812 outputs instructions (e.g., via the interface circuitry 800) to the communication interface 110 to operate based on the final selected RX delay, TX delay, RD cycle, and the RX reference clock. The interface circuitry 800 can output a first control signal to the TX PDL 210 to set the TX delay, a second control signal to the RX PDL 212 to set the RX delay, and a third control signal to a select terminal of the MUX 702 to RX reference clock and fourth to set the RD cycle. At block 916, normal operation occurs based on the selected sampling/tuning point parameters, as further described below in conjunction with FIG. 10. If the core processor 102 receives an instruction (e.g., via the interface circuitry 800) to recalibrate the sampling/tuning point parameters, control returns to block 902.

FIG. 10 is a flowchart representative of a method and/or example operations 916 that may be executed and/or instantiated by core processor 102 of FIGS. 1 and 8 to facilitate normal operation. The operations 916 can be performed by any one or combination of the circuitry shown in FIGS. 1-5. Although the instructions and/or operations of FIG. 10 are described in conjunction with the core processor 102 of FIGS. 1 and 8, the instructions and/or operations may be described in conjunction with any type of circuit that implements processing circuitry. Some processes shown in FIG. 10 may be performed in orders other than described, and many processes may be performed concurrently in parallel. Furthermore, processes shown in FIG. 10 may be omitted or substituted in some examples of the present description.

The machine-readable instructions and/or the operations 916 of FIG. 10 begin at block 1002, at which the sampling/tuning point application circuitry 812 monitors condition(s). For example, the sampling/tuning point application circuitry 812 may include or interface with one or more sensors, clocks, etc. to access information related to one or more condition(s) (e.g., temperature or humidity data from a sensor, age data from a clock or timer or a counter, accessible corner position from die, etc.). At block 1004, the sampling/tuning point application circuitry 812 determines if the monitored condition(s) correspond to or exceed particular sampling/tuning point(s) stored in the storage 814. As described above, the predictive compensation model circuitry 808 can generate multiple different sampling/tuning points for generated polygon representation(s) that correspond to different conditions (e.g., ranges of temperatures and/or ranges of operation time/age, etc.). Such sampling/tuning points and the conditions that they correspond to are stored in the storage 814. Accordingly, the sampling/tuning point application circuitry 812 can access the conditions for the stored sampling/tuning point parameters and determine if any match or exceed the current conditions.

If the sampling/tuning point application circuitry 812 determines that the condition(s) do not correspond to other sampling/tuning points stored in the storage 814 (block 1004: NO), control returns to block 1002. If the sampling/tuning point application circuitry 812 determines that the condition(s) corresponds to other sampling/tuning point(s) stored in the storage 814 (block 1004: YES), the sampling/tuning point application circuitry 812 selects and applies (e.g., programs the communication interface 110) the sampling/tuning point parameters that correspond to the current conditions (block 1006). If there are multiple sampling/tuning points that correspond to the current conditions, the sampling/tuning point application circuitry 812 can select the sampling/tuning point parameters that correspond to a desirable (e.g., optimal) stability indicator. Thus, the flowchart of FIG. 10 provides on-the-fly sampling/tuning point parameter tuning and tracking without requiring recalibration. After block 1006, control returns to block 1002 to continue to monitor/track condition(s).

FIG. 11A illustrates an example polygon representation, without the need for going over all the combination of TX and RX delays, 1100 generated by the core processor 102 using a fast polygon generation technique for a specific protocol and reference clock configuration based on a boundary detection of a polygon. For example, the core processor 102 can first apply the minimal RX and TX delay for a particular RD cycle and sample data that is known based on the RX delay, TX delay, and RD cycle. If the sampled data matched the known data, the core processor 102 tags the sampling/tuning point (e.g., “A”) as successful. If the sampled data does not match the known data, the core processor 102 can adjust one or more of the TX delay or RX delay and repeat until the first “corner” successful sampling/tuning point of the polygon representation is found.

After the first successful sampling/tuning point (“A”) is determined, the core processor 102 increases the RX delay and maintains the TX delay and continues to compare known data to sampled data until the highest successful RX delay is determined (e.g., corresponding to sampling “B”). Also, after the first successful sampling/tuning point (“A”) is determined, the core processor 102 increases the TX delay and maintains the RX delay and continues to compare known data to sampled data until the highest successful TX delay is determined (e.g., corresponding to sampling “C”). After points A, B, and C are determined, the core processor 102 can first apply the maximum RX and TX delay for a particular RD cycle and sample data that is known based on the RX delay, TX delay, RX reference clock and RD cycle. If the sampled data matched the known data, the core processor 102 tags the sampling/tuning point (e.g., “D”) as successful. If the sampled data does not match the known data, the core processor 102 can adjust one or more of the TX delay or RX delay and repeat until the first “corner” successful sampling/tuning point of the polygon representation is found. After the maximum successful sampling/tuning point (“C”) is determined, the core processor 102 decreases the RX delay and maintains the TX delay and continues to compare known data to sampled data until the highest successful RX delay is determined (e.g., corresponding to sampling “F”). Also, after the maximum successful sampling/tuning point (“D”) is determined, the core processor 102 decreases the TX delay and maintains the RX delay and continues to compare known data to sampled data until the highest successful TX delay is determined (e.g., corresponding to sampling “E”). The core processor 102 can then generate a polygon representation based on the determined points A, B, C, D, E, and F.

FIG. 11B illustrates an example polygon representation 1102 generated by the core processor 102 using a robust polygon generation technique (e.g., a rigorous brute force polygon generation technique). For example, the core processor 102 can first apply the minimal RX and TX delay for a particular RD cycle and sample data that is known based on the RX delay, TX delay, RX reference clock and RD cycle. If the sampled data matched the known data, the core processor 102 tags the sampling/tuning point (e.g., “A”) as successful. If the sampled data does not match the known data, the core processor 102 can adjust one or more of the TX delay or RX delay and repeat until the first “corner” successful sampling/tuning point of the polygon representation is found.

After the first successful sampling/tuning point (“A”) is determined, the core processor 102 increases the RX delay and maintains the TX delay and continues to compare known data to sampled data until the highest successful RX delay is determined (e.g., corresponding to sampling “B”). After the second successful corner sampling/tuning point (“B”) is determined, the core processor 102 increases the RX delay and/or increases the TX delay and continues to compare known data to sampled data until the highest successful RX delay is developed along the edge “1b” until successful corner (“C”) is identified, which corresponds to the maximum RX delay. After the third successful corner sampling/tuning point (“C”) is determined, the core processor 102 increases the TX delay and continues comparing known data to sampled data until the maximum RX and TX delay sampling/tuning point is determined (“D”) that results in successful sampling. After the maximum successful sampling/tuning point (“C”) is determined, the core processor 102 decreases the RX delay and maintains the TX delay and continues to compare known data to sampled data until the highest successful RX delay is determined (e.g., corresponding to sampling “E”). After the fifth successful corner sampling/tuning point (“E”) is determined, the core processor 102 decreases the RX delay and/or decreases the TX delay and continues to compare known data to sampled data until the highest successful RX delay is developed along the edge “1e” until successful corner (“F”) is identified. After the sixth successful corner sampling/tuning point “F” is determined, the core processor 102 continues testing while decreasing the TX delay to verify the 1f edge. The core processor 102 determines the polygon representation based on the edges A, B, C, D, E, F, and edges 1a, 1b, 1c, 1d, 1e, 1f. Although FIGS. 11A and 11B correspond to a particularly shaped polygon, the size, shape, dimensions, etc. for a polygon representation may be differed. Additionally, although FIGS. 11A and 11B illustrate two techniques for testing sampling/tuning points to generate a polygon representation, there are other ways to select sampling/tuning points to generate a polygon representation of successful sampling/tuning point parameters per for a specific protocol and reference clock configuration. The polygons of FIGS. 11A and 11B correspond to different delay(s) (e.g., RX and TX delay) the result in successful sampling of data.

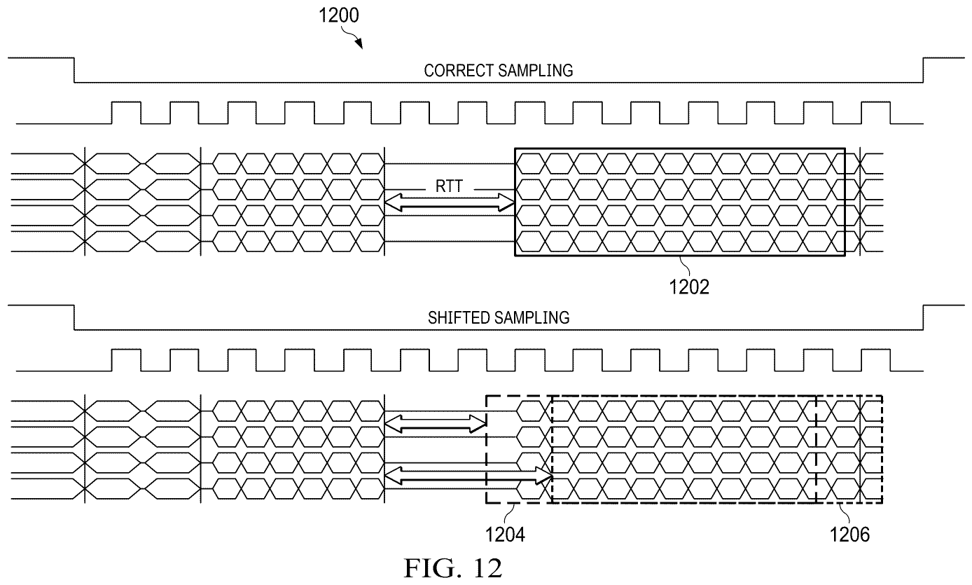

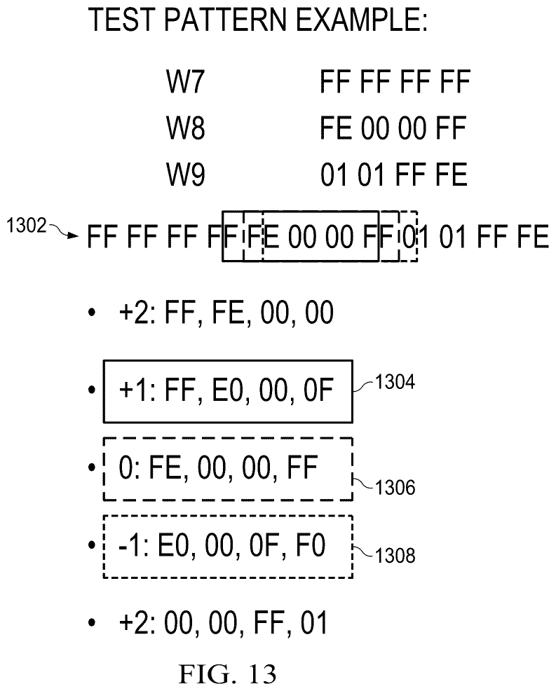

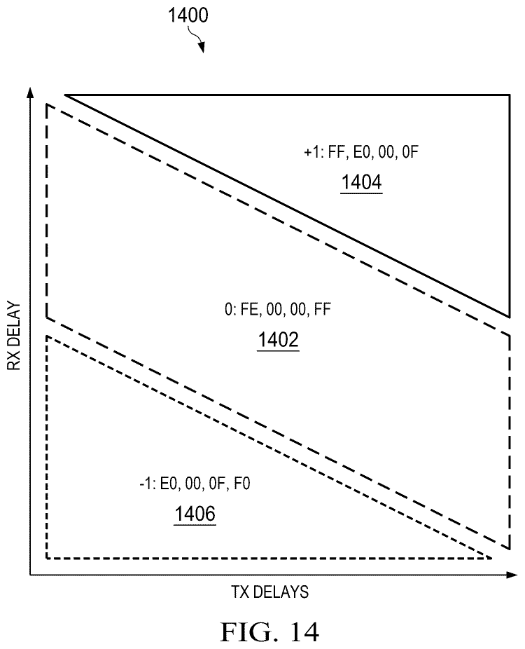

FIG. 12 illustrates example sampling 1200 with different shifts in the delay (represented by 4 bits shift in QSPI protocol configuration case). A first example sampling 1202 corresponds to sampling with zero delay (e.g., sampling after the dummy signal). In some examples, the first sampling 1202 corresponds to the RD cycle that relates to RX-ref B: Pad loopback of FIGS. 3 and 4. A second example sampling 1204 corresponds to sampling with a positive shift delay of one (e.g., sampling before the sampling 1202 by one sampling period). In some examples, the second sampling 1204 corresponds to the RD cycle that relates to RX-ref A: no loopback of FIGS. 3 and 4. A third example sampling 1206 corresponds to sampling with a negative shift delay of one (e.g., sampling after the first sampling 1202 by one period). In some examples, the third sampling 1206 corresponds to the RD cycle that relates to RX-ref C: external loopback or DQS of FIGS. 3 and 4. As further described below in conjunction with FIGS. 13 and 14.

FIG. 13 illustrates an example data signal 1302 that includes a dummy signal (corresponding to W7), first read data (corresponding to W8) and second read data (corresponding to W9). FIG. 13 includes a first sample 1304 of the data signal 1302, a second sample 1306 of the data signal 1302, and a third sample 1309 of the data signal 1302. The first sample 1304 (e.g., corresponding to a first RD cycle) corresponds to the second sampling 1204 of FIG. 12, the second sample 1306 (e.g., corresponding to a second RD cycle) corresponds to the first sampling 1202 of FIG. 12, and the third sampling 1308 (e.g., corresponding to a third RD cycle) corresponds to the third sampling 1206 of FIG. 12. As described above, each sampling corresponds to a different polygon representation, as further described below in conjunction with FIG. 14. In some examples, additional shifted delays can be used to determine additional or alternative polygon representations.

FIG. 14 illustrates an example visual representation 1400 of example polygon representations 1404, 1402, 1406 corresponding to the different shifted delays of FIG. 13. For example, the polygon representation 1402 corresponds to the RX delay and TX delay combinations that result in successful sampling for the third sample 1306 of FIG. 13 (e.g., a RD cycle corresponding to no shift delay or RX-ref B: Pad loopback). The polygon representation 1404 corresponds to the RX delay and TX delay combinations that result in successful sampling for the first sample 1304 of FIG. 13 (e.g., a RD cycle corresponding to positive shift delay of one or RX-ref A: no loopback). The polygon representation 1406 corresponds to the RX delay and TX delay combinations that result in successful sampling for the third sample 1308 of FIG. 13 (e.g., a RD cycle corresponding to negative shift delay of one or RX-ref C: external loopback or DQS).

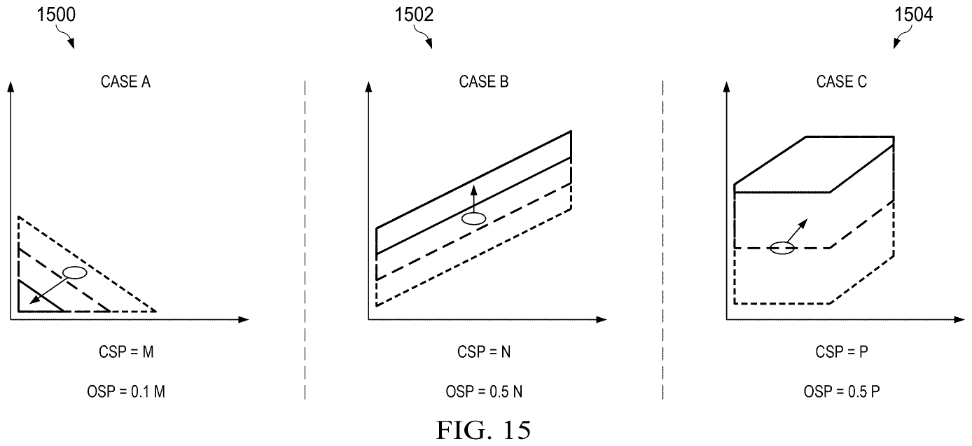

FIG. 15 illustrates three example polygons per for a specific protocol and reference clock configuration representations 1500, 1502, 1504 and the effect of applying a PCM to a polygon. In the first polygon representation 1500, the core processor 102 determines the sampling/tuning point to be ‘m’ corresponding to an amount of TX and RX delay for the RD cycle that corresponds to the polygon representation 1500. Additionally, a PCM has been generated for the RD cycle that represents the effect of one or more conditions on the sampling/tuning point. The PCM may consider and/or be tuned to a specific protocol and reference clock configuration. For example, the PCM causes the polygon representation 1500 to shrink toward the origin of the graph (e.g., decreasing the RX and TX delay) at a linear rate of 0.1 for a particular one or more conditions. The shrinking is due to worse case PCM implementation that generates the minimal polygon representation. However, other PCM may result in different results, such as an expansion, shift, etc.). In the second polygon representation 1502, the core processor 102 determines the sampling/tuning point to be ‘n’ corresponding to an amount of TX and RX delay for the RD cycle that corresponds to the polygon representation 1502. Additionally, a PCM has been generated for the RD cycle that represents the effect of one or more conditions on the sampling/tuning point. For example, the PCM causes the polygon representation 1500 to shrink upward (e.g., increasing the RX delay) at a linear rate of 0.5 for a particular one or more conditions. In the third polygon representation 1504, the core processor 102 determines the sampling/tuning point to be ‘p’ corresponding to an amount of TX and RX delay for the RD cycle that corresponds to the polygon representation 1504. Additionally, a PCM has been generated for the RD cycle that represents the effect of one or more conditions on the sampling/tuning point. For example, the PCM causes the polygon representation 1500 to shrink toward the up and to the right (e.g., increasing the RX and TX delay) at a linear rate of 0.1 for a particular one or more conditions. The PCM of each polygon representation 1500, 1502, 1504 of FIG. 15 corresponds to an amount and a direction (e.g., a linear vector-based representation). However, the PCM may correspond to a different (e.g., non-linear model) that causes a polygon representation to adjust based on the effect changing the conditions has on a sampling/tuning point and/or polygon representation.

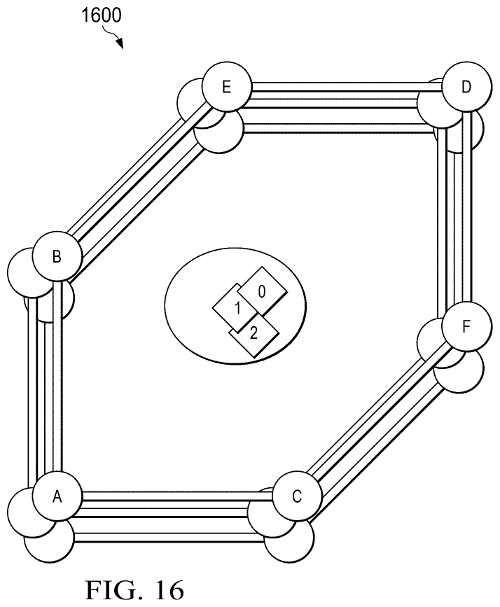

FIG. 16 illustrates an alterative example of a polygon representation 1600 and the effect of application of a PCM to the polygon representation 1600 and the PCM can generate a range of possible tuning points in a non-linear manner. In the example of FIG. 16, the core processor 102 generates a first polygon representation for a RD cycle with a selected sampling/tuning point of ‘0.’ The first polygon representation corresponds to first initial conditions (e.g., a first temperature range lower than a second temperature range, a first age range, etc.) When the core processor 102 applies a PCM corresponding to second environmental condition(s) (e.g., the second temperature range, a second age range older than the first age range, etc.), the core processor 102 adjusts the selected sampling/tuning point using the PCM from ‘0’ to ‘1.’ When the core processor 102 applies a PCM corresponding to third condition(s) (e.g., a third temperature range higher than the second temperature range, a third age range older than the second age range, etc.), the core processor 102 adjusts the selected sampling/tuning point using the PCM from ‘1’ to ‘2.’ As shown in FIG. 16, the polygon representations and the sampling/tuning points change from ‘0’ to ‘1’ to ‘2’ in a non-linear manner.

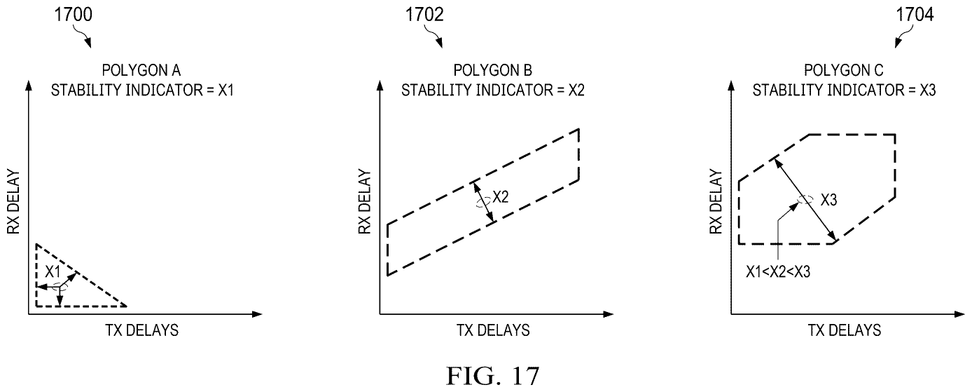

FIG. 17 illustrates generated example polygon representations 1700, 1702, 1704 for different RD cycles and the corresponding stability indicators for the selected sampling/tuning points of each polygon representation. The first polygon representation 1700 corresponds to a first RD cycle and has a stability indicator of X1, which is the closest distance from the selected sampling/tuning point to the closest edge of the polygon representation 1700. The second polygon representation 1702 corresponds to a second RD cycle and has a stability indicator of X2, which is the closest distance from the selected sampling/tuning point to the closest edge of the polygon representation 1702. The third polygon representation 1704 corresponds to a third RD cycle and has a stability indicator of X3, which is the closest distance from the selected sampling/tuning point to the closest edge of the polygon representation 1704. In the example of FIG. 17, the core processor 102 selects one of the sampling/tuning points of the polygon representations 1700, 1702, 1704 based on the stability indicator. For example, the core processor 102 determines that the stability indicator of the sampling/tuning point of the third polygon 1704 is larger than the stability indicators of the sampling/tuning points of the first and second polygons 1700, 1702 (assuming the optimization criteria is constantly increasing). Accordingly, the core processor 102 selects the sampling/tuning point of the third polygon representation 1704 because the corresponding stability indicator is the largest of the three polygon representations.

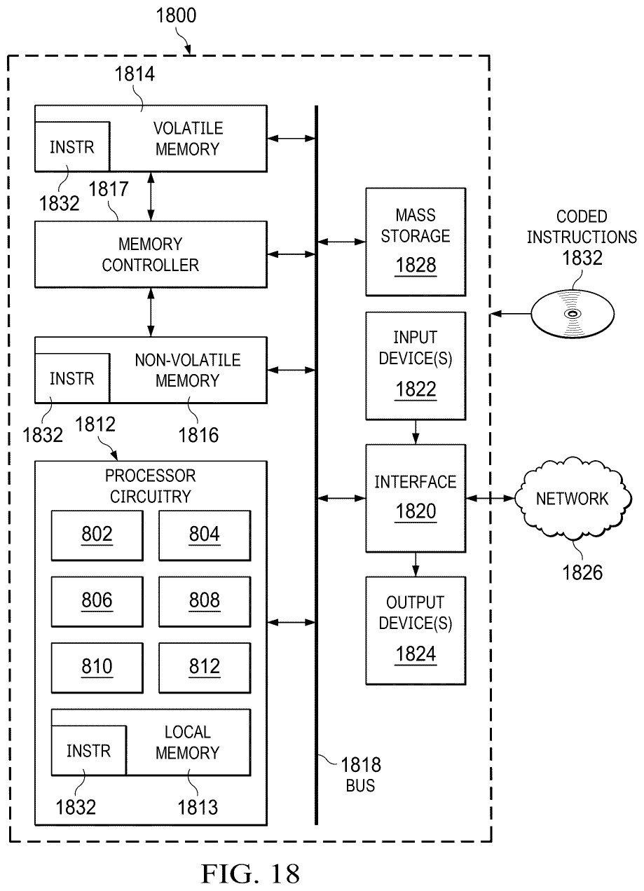

FIG. 18 is a block diagram of an example programmable circuitry platform 1800 structured to execute and/or instantiate the example machine-readable instructions and/or the example operations of FIGS. 9-10 to implement the core processor 102 of FIG. 8. The programmable circuitry platform 1800 can be, for example, a server, a personal computer, a workstation, a self-learning machine (e.g., a neural network), a mobile device (e.g., a cell phone, a smart phone, a tablet such as an iPad™), a personal digital assistant (PDA), an Internet appliance, a gaming console, a headset (e.g., an augmented reality (AR) headset, a virtual reality (VR) headset, etc.) or other wearable or Internet of Things (IoT) device, or any other type of computing and/or electronic device.

The programmable circuitry platform 1800 of the illustrated example includes programmable circuitry 1812. The programmable circuitry 1812 of the illustrated example is hardware. For example, the programmable circuitry 1812 can be implemented by one or more integrated circuits, logic circuits, FPGAs, microprocessors, CPUs, GPUs, VPUs, DSPs, and/or microcontrollers from any desired family or manufacturer. The programmable circuitry 1812 may be implemented by one or more semiconductor based (e.g., silicon based) devices. In this example, the programmable circuitry 1812 implements the parameter selection circuitry 802, the polygon representation determination circuitry 804, the sampling/tuning point determination circuitry 806, the predictive compensation model 808, the comparator 810, and the sampling/tuning point application circuitry 812.

The programmable circuitry 1812 of the illustrated example includes a local memory 1813 (e.g., a cache, registers, etc.). The programmable circuitry 1812 of the illustrated example is in communication with main memory 1814, 1816, which includes a volatile memory 1814 and a non-volatile memory 1816, by a bus 1818. The volatile memory 1814 may be implemented by Synchronous Dynamic Random Access Memory (SDRAM), Dynamic Random Access Memory (DRAM), RAMBUS® Dynamic Random Access Memory (RDRAM®), and/or any other type of RAM device. The non-volatile memory 1816 may be implemented by flash memory and/or any other desired type of memory device. Access to the main memory 1814, 1816 of the illustrated example is controlled by a memory controller 1817. In some examples, the memory controller 1817 may be implemented by one or more integrated circuits, logic circuits, microcontrollers from any desired family or manufacturer, or any other type of circuitry to manage the flow of data going to and from the main memory 1814, 1816. In some examples, one of the local memory 1813, the volatile memory 1814, or the non-volatile memory 1816 implements the storage 814 of FIG. 8.

The programmable circuitry platform 1800 of the illustrated example also includes interface circuitry 1820. The interface circuitry 1820 may be implemented by hardware in accordance with any type of interface standard, such as an Ethernet interface, a universal serial bus (USB) interface, a Bluetooth® interface, a near field communication (NFC) interface, a Peripheral Component Interconnect (PCI) interface, and/or a and/or a Serial Peripheral Interface (SPI) and/or Peripheral Component Interconnect Express (PCIe) interface. In some examples, the interface circuitry 1820 implements the interface circuit 800 of FIG. 8.

In the illustrated example, one or more input devices 1822 are connected to the interface circuitry 1820. The input device(s) 1822 permit(s) a user (e.g., a human user, a machine user, etc.) to enter data and/or commands into the programmable circuitry 1812. The input device(s) 1822 can be implemented by, for example, an audio sensor, a microphone, a camera (still or video), a keyboard, a button, a mouse, a touchscreen, a trackpad, and/or a voice recognition system.

One or more output devices 1824 are also connected to the interface circuitry 1820 of the illustrated example. The output device(s) 1824 can be implemented, for example, by display devices (e.g., a light emitting diode (LED), an organic light emitting diode (OLED), a liquid crystal display (LCD), a cathode ray tube (CRT) display, an in-place switching (IPS) display, a touchscreen, etc.), a tactile output device, and/or speaker. The interface circuitry 1820 of the illustrated example, thus, typically includes a graphics driver card, a graphics driver chip, and/or graphics processor circuitry such as a GPU.

The interface circuitry 1820 of the illustrated example also includes a communication device such as a transmitter, a receiver, a transceiver, a modem, a residential gateway, a wireless access point, and/or a network interface to facilitate exchange of data with external machines (e.g., computing devices of any kind) by a network 1826. The communication can be by, for example, an Ethernet connection, a digital subscriber line (DSL) connection, a telephone line connection, a coaxial cable system, a satellite system, a beyond-line-of-sight wireless system, a line-of-sight wireless system, a cellular telephone system, an optical connection, etc.

The programmable circuitry platform 1800 of the illustrated example also includes one or more mass storage discs or devices 1828 to store firmware, software, and/or data. Examples of such mass storage discs or devices 1828 include magnetic storage devices (e.g., floppy disk, drives, HDDs, etc.), optical storage devices (e.g., Blu-ray disks, CDs, DVDs, etc.), RAID systems, and/or solid-state storage discs or devices such as flash memory devices and/or SSDs.

The machine readable instructions 1832, which may be implemented by the machine readable instructions of FIGS. 9-10, may be stored in the mass storage device 1828, in the volatile memory 1814, in the non-volatile memory 1816, and/or on at least one non-transitory computer readable storage medium such as a CD or DVD which may be removable.

An example manner of implementing the Device 100, the core processor 102, and/or the communication interface 110 of FIG. 1 is illustrated in FIGS. 2-5. However, one or more of the elements, processes and/or devices illustrated in FIGS. 1-2 may be combined, divided, re-arranged, omitted, eliminated and/or implemented in any other way.

Further, the interface circuitry 800, the parameter selection circuitry 802, the polygon representation determination circuitry 804, the sampling/tuning point determination circuitry 806, the PCM circuitry 808, the comparator 810, the sampling/tuning point application circuitry 812, and/or the storage 814 of FIG. 8 may be implemented by hardware, software, firmware and/or any combination of hardware, software and/or firmware. As a result, for example, any of the interface circuitry 800, the parameter selection circuitry 802, the polygon representation determination circuitry 804, the sampling/tuning point determination circuitry 806, the PCM circuitry 808, the comparator 810, the sampling/tuning point application circuitry 812, and/or the storage 814 of FIG. 8 could be implemented by one or more analog or digital circuit(s), logic circuits, programmable processor(s), programmable controller(s), graphics processing unit(s) (GPU(s)), digital signal processor(s) (DSP(s)), application specific integrated circuit(s) (ASIC(s)), programmable logic device(s) (PLD(s)) and/or field programmable logic device(s) (FPLD(s)).

When reading any of the apparatus or system claims of this patent to cover a purely software and/or firmware implementation, at least one of the interface circuitry 800, the parameter selection circuitry 802, the polygon representation determination circuitry 804, the sampling/tuning point determination circuitry 806, the PCM circuitry 808, the comparator 810, the sampling/tuning point application circuitry 812, and/or the storage 814 of FIG. 8 is/are hereby expressly defined to include a non-transitory computer readable storage device or storage disk such as a memory, a digital versatile disk (DVD), a compact disk (CD), a Blu-ray disk, etc., including the software and/or firmware. Further still, the interface circuitry 800, the parameter selection circuitry 802, the polygon representation determination circuitry 804, the sampling/tuning point determination circuitry 806, the PCM circuitry 808, the comparator 810, the sampling/tuning point application circuitry 812, and/or the storage 814 of FIG. 8 may include one or more elements, processes and/or devices in addition to, or instead of, those illustrated in FIG. 8, and/or may include more than one of any or all of the illustrated elements, processes, and devices. As used herein, the phrase “in communication,” including variations thereof, encompasses direct communication and/or indirect communication through one or more intermediary components, and does not require direct physical (e.g., wired) communication and/or constant communication, but rather also includes selective communication at periodic intervals, scheduled intervals, aperiodic intervals, and/or one-time events.

Flowcharts representative of example hardware logic, machine-readable instructions, hardware implemented state machines, and/or any combination thereof for implementing the core processor 102 of FIGS. 1 and 8 are shown in FIGS. 9-10. The machine-readable instructions may be one or more executable programs or portion(s) of an executable program for execution by a computer processor. The program may be embodied in software stored on a non-transitory computer readable storage medium such as a CD-ROM, a floppy disk, a hard drive, a DVD, a Blu-ray disk, or a memory associated with the processor, but the entire program and/or parts thereof could alternatively be executed by a device other than the processor and/or embodied in firmware or dedicated hardware.

Further, although the example program is described with reference to the flowcharts illustrated in FIGS. 9-10, many other methods of implementing the core processor 102 may alternatively be used. For example, the order of execution of the blocks may be changed, and/or some of the blocks described may be changed, eliminated, or combined. Also or alternatively, any or all of the blocks may be implemented by one or more hardware circuits (e.g., discrete and/or integrated analog and/or digital circuitry, a field-programmable gate array (FPGA), an application-specific integrated circuit (ASIC), a comparator, an operational-amplifier (op-amp), a logic circuit, etc.) structured to perform the corresponding operation without executing software or firmware.

The machine-readable instructions described herein may be stored in one or more of a compressed format, an encrypted format, a fragmented format, a compiled format, an executable format, a packaged format, etc. Machine-readable instructions as described herein may be stored as data (e.g., portions of instructions, code, representations of code, etc.) that may be utilized to create, manufacture, and/or produce machine executable instructions. For example, the machine-readable instructions may be fragmented and stored on one or more storage devices and/or computing devices (e.g., servers). The machine-readable instructions may require one or more of installation, modification, adaptation, updating, combining, supplementing, configuring, decryption, decompression, unpacking, distribution, reassignment, compilation, etc. in order to make them directly readable, interpretable, and/or executable by a computing device and/or other machine. For example, the machine-readable instructions may be stored in multiple parts, which are individually compressed, encrypted, and stored on separate computing devices, in which the parts when decrypted, decompressed, and combined form a set of executable instructions that implement a program such as that described herein.

In another example, the machine-readable instructions may be stored in a state in which they may be read by a computer, but require addition of a library (e.g., a dynamic link library (DLL)), a software development kit (SDK), an application programming interface (API), etc. in order to execute the instructions on a particular computing device or other device. In another example, the machine-readable instructions may be configured (e.g., settings stored, data input, network addresses recorded, etc.) before the machine-readable instructions and/or the corresponding program(s) can be executed in whole or in part. As a result, the described machine-readable instructions and/or corresponding program(s) encompass such machine-readable instructions and/or program(s) regardless of the particular format or state of the machine-readable instructions and/or program(s) when stored or otherwise at rest or in transit.

The machine-readable instructions described herein can be represented by any past, present, or future instruction language, scripting language, programming language, etc. For example, the machine-readable instructions may be represented using any of the following languages: assembly language, C, C++, Java, C-sharp, Perl, Python, JavaScript, HyperText Markup Language (HTML), Structured Query Language (SQL), Swift, etc.

As mentioned above, the example processes of FIG. 6 may be implemented using executable instructions (e.g., computer and/or machine-readable instructions) stored on a non-transitory computer and/or machine-readable medium such as a hard disk drive, a flash memory, a read-only memory, a compact disk, a digital versatile disk, a cache, a random-access memory and/or any other storage device or storage disk in which information is stored for any duration (e.g., for extended time periods, permanently, for brief instances, for temporarily buffering, and/or for caching of the information). As used herein, the term non-transitory computer readable medium is expressly defined to include any type of computer readable storage device and/or storage disk and to exclude propagating signals and to exclude transmission media.

Although certain example methods, apparatus and articles of manufacture have been described herein, the scope of coverage of this patent is not limited thereto. On the contrary, this patent covers all methods, apparatus and articles of manufacture fairly falling within the scope of the claims of this patent.

Descriptors “first,” “second,” “third,” etc. are used herein when identifying multiple elements or components which may be referred to separately. Unless otherwise specified or known based on their context of use, such descriptors do not impute any meaning of priority, physical order, or arrangement in a list, or ordering in time but are merely used as labels for referring to multiple elements or components separately for case of understanding the described examples. In some examples, the descriptor “first” may be used to refer to an element in the detailed description, while the same element may be referred to in a claim with a different descriptor such as “second” or “third.” In such instances, such descriptors are used merely for ease of referencing multiple elements or components.

In the description and in the claims, the terms “including” and “having” and variants thereof are to be inclusive in a manner similar to the term “comprising” unless otherwise noted. Unless otherwise stated, “about,” “approximately,” or “substantially” preceding a value means+/−10 percent of the stated value. In another example, “about,” “approximately,” or “substantially” preceding a value means+/−5 percent of the stated value. IN another example, “about,” “approximately,” or “substantially” preceding a value means +/−1 percent of the stated value.

The term “couple” “coupled”, “couples”, and variants thereof, as used herein, may cover connections, communications, or signal paths that enable a functional relationship consistent with this description. For example, if device A generates a signal to control device B to perform an action, in a first example device A is coupled to device B, or in a second example device A is coupled to device B through intervening component C if intervening component C does not substantially alter the functional relationship between device A and device B such that device B is controlled by device A via the control signal generated by device A. Moreover, the terms “couple,” “coupled,” “couples,” or variants thereof, includes an indirect or direct electrical or mechanical connection.

A device that is “configured to” perform a task or function may be configured (e.g., programmed and/or hardwired) at a time of manufacturing by a manufacturer to perform the function and/or may be configurable (or re-configurable) by a user after manufacturing to perform the function and/or other additional or alternative functions. The configuring may be through firmware and/or software programming of the device, through a construction and/or layout of hardware components and interconnections of the device, or a combination thereof.

Although not all separately labeled in the FIGS. 1-4, components or elements of systems and circuits illustrated therein have one or more conductors or terminus that allow signals into and/or out of the components or elements. The conductors or terminus (or parts thereof) may be referred to herein as pins, pads, terminals (including input terminals, output terminals, reference terminals, and ground terminals, for instance), inputs, outputs, nodes, and interconnects.

As used herein, a “terminal” of a component, device, system, circuit, integrated circuit, or other electronic or semiconductor component, generally refers to a conductor such as a wire, trace, pin, pad, or other connector or interconnect that enables the component, device, system, etc., to electrically and/or mechanically connect to another component, device, system, etc. A terminal may be used, for instance, to receive or provide analog or digital electrical signals (or simply signals) or to electrically connect to a common or ground reference. Accordingly, an input terminal or input is used to receive a signal from another component, device, system, etc. An output terminal or output is used to provide a signal to another component, device, system, etc. Other terminals may be used to connect to a common, ground, or voltage reference, e.g., a reference terminal or ground terminal. A terminal of an IC or a PCB may also be referred to as a pin (a longitudinal conductor) or a pad (a planar conductor). A node refers to a point of connection or interconnection of two or more terminals. An example number of terminals and nodes may be shown. However, depending on a particular circuit or system topology, there may be more or fewer terminals and nodes. However, in some instances, “terminal,” “node,” “interconnect,” “pad,” and “pin” may be used interchangeably.

The terms “or” and “and/or” as used, for example, in a form such as A, B, or C or A, B, and/or C refers to any combination or subset of A, B, C such as (1) A alone, (2) B alone, (3) C alone, (4) A with B, (5) A with C, (6) B with C, or (7) A with B and with C.

Modifications are possible in the described embodiments, and other embodiments are possible, within the scope of the claims.

What is claimed is:

1. A device comprising:
a communication interface configurable to receive a data signal; and
processor circuitry coupled to the communication interface and configurable to:
determine a first timing for sampling the data signal for a first value of a condition;
determine a second timing for sampling the data signal for a second value of the condition using the first timing and a predictive compensation model, wherein the second timing is different from the first timing;
measure the condition;
select the first timing or the second timing using the measured condition; and
program the communication interface to sample using the selected timing.

2. The device of claim 1,
wherein the condition is temperature,
wherein the first value of the temperature is a different temperature than the second value of the temperature, and
wherein the first timing has a different delay than a delay of the second timing.

3. The device of claim 1, wherein the predictive compensation model includes different delays for varying temperatures.

4. The device of claim 1, wherein the communication interface includes a half-duplex serial peripheral interface.

5. The device of claim 1, wherein the processing circuitry is configurable to:
determine a third timing for sampling the data signal for a third value of the condition using the first timing or using the second timing, wherein the third timing is different from the first timing and different from the second timing; and
select the first timing, the second timing, or the third timing using measured condition.

6. The device of claim 1, wherein the predictive compensation model adjusts the first timing using a mathematical function that is based on estimations of an effect of the condition on success of the first timing.

7. The device of claim 1, wherein the processor circuitry is to determine the first timing by generating a polygon representation based on successful sampling of data for different tuning point parameters, the first timing corresponding to a point in the polygon representation.

8. The device of claim 7, wherein the processor circuitry is configurable to generate the polygon representation by:
transmitting instructions to write first data to a peripheral device based on the different tuning point parameters;
sampling second data from the peripheral device based on the different tuning point parameters; and
determining a portion of the sampling was successful based on the first data matching the second data; and
generating the polygon representation using the portion of the different tuning point parameters corresponding to the portion of the sampling.

9. The device of claim 1, wherein the condition is at least one of an environmental condition or a die condition, the environmental condition corresponding to one or more of temperature or humidity, the die condition corresponding to age of the communication interface, structure of the communication interface, or location of the communication interface when implemented in a wafer.

10. A method comprising:
determining a first timing for sampling a data signal for a first value of a condition;
determining a second timing for sampling the data signal for a second value of the condition using the first timing and a predictive compensation model, wherein the second timing is different from the first timing;
measuring the condition;
selecting the first timing or the second timing using the measured condition; and
programming a communication interface to sample using the selected timing.

11. The method of claim 10,
wherein the condition is temperature,
wherein the first value of the temperature is a different temperature than the second value of the temperature, and
wherein the first timing has a different delay than a delay of the second timing.

12. The method of claim 10, wherein the predictive compensation model includes different delays for different temperatures.

13. The method of claim 10, wherein the communication interface includes a serial peripheral interface.

14. The method of claim 10, including:
determining a third timing for sampling the data signal for a third value of the condition using the first timing or using the second timing, wherein the third timing is different from the first timing and different from the second timing; and
selecting the first timing, the second timing, or the third timing using measured condition.

15. The method of claim 10, wherein the predictive compensation model adjusts the first timing using a mathematical function that is based on estimations of an effect of the condition on success of the first timing.

16. The method of claim 10, including determining the first timing by generating a polygon representation based on successful sampling of data for different tuning point parameters, the first timing corresponding to a point in the polygon representation.

17. The method of claim 16, wherein the generating of the polygon representation includes:
transmitting instructions to write first data to a peripheral device based on the different tuning point parameters;
sampling second data from the peripheral device based on the different tuning point parameters; and
determining a portion of the sampling was successful based on the first data matching the second data; and
generating the polygon representation using the portion of the different tuning point parameters corresponding to the portion of the sampling.

18. A system comprising:
a communication interface configurable to:
transmit a clock signal and a first data signal based on tuning point parameters; and
sample a second data signal based on the tuning point parameters; and
a peripheral device coupled to the communication interface, the peripheral device configurable to:
receive the clock signal and the first data signal; and
transmit the second data signal, the second data signal corresponding to the first data signal; and
processor circuitry coupled to the communication interface, the processor circuitry configurable to:
determine a first timing for sampling the second data signal for a first value of an condition, the first timing corresponding to the tuning point parameters;
determine a second timing for sampling the second data signal for a second value of the condition using the first timing and a predictive compensation model, wherein the second timing is different from the first timing;
measure the condition;
select the first timing or the second timing using the measured condition; and
program the communication interface to use the selected timing.

19. The system of claim 18,
wherein the condition is temperature;
wherein the first value of the temperature is a different temperature than the second value of the temperature, and
wherein the first timing has a different delay than a delay of the second timing.

20. The system of claim 18, wherein the predictive compensation model includes different delays for different temperatures.
